(19) United States
(12) Patent Application Publication
(10) Pub. No.: US 2010/0079640 A1
(43) Pub. Date: Apr. 1, 2010

(54) Image Sensor and Method For Manufacturing the Same

(76) Inventor: JOON HWANG, Chungbuk (KR)

Correspondence Address: Joon Hwang, 201-710, Samjeong Apt., Yullyang-dong, Sangdang-gu, Cheongju-si, Chungbuk, KR

(21) Appl. No.: 12/566,813

(22) Filed: Sep. 25, 2009

(30) Foreign Application Priority Data
Sep. 30, 2008 (KR) 10-2008-0096094

(51) Int. Cl. H04N 5/335; H01L 21/30

(52) U.S. Cl. 348/294; 438/73; 257/E21.211

(57) ABSTRACT

An image sensor and a method for manufacturing the same are provided. The image sensor can include a readout circuitry on a first substrate, a metal line on the first substrate and electrically connected to the readout circuitry, an insulation layer on the metal line, an electrode on the insulation layer, an image sensing device on the electrode, and a pixel separation region in the image sensing device.

### CROSS-REFERENCE TO RELATED APPLICATIONS

This application claims the benefit under 35 U.S.C. §119 of Korean Patent Application No. 10-2008-0096094, filed on Sep. 30, 2008, which is hereby incorporated by reference in its entirety.

### BACKGROUND

An image sensor is a semiconductor device that converts an optical image into an electric signal. Image sensors can be classified as charge coupled device (CCD) image sensors and complementary metal oxide semiconductor (CMOS) image sensors (CIS).

During the fabrication of an image sensor, a photodiode can be formed in a substrate using ion implantation. As the size of photodiodes continue to get smaller for the purpose of increasing the number of pixels without increasing chip size, the area of a light receiving portion in an image sensor is also reduced. This results in a reduction in image quality.

Also, since the height of a stack does not reduce as much as the area of the light receiving portion reduces, the number of photons incident to the light receiving portion also decreases. This is due to diffraction of light sometimes called an Airy disk.

To address this limitation, a photodiode can be formed using amorphous silicon (Si), or readout circuitry can be formed in a silicon (Si) substrate using a method such as wafer-to-wafer bonding. Also, a photodiode can be formed on and/or over the readout circuitry (referred to as a three-dimensional (3D) image sensor). The photodiode can be connected with the readout circuitry through a metal line.

In the related art, contact failures often occur between a photodiode and a metal line, and it is therefore necessary to perform a process of forming a contact between the photodiode and the metal line. However, this results in an increase in dark current.

Furthermore, both the source and the drain of the transfer transistor are heavily doped with N-type impurities, leading to a charge sharing phenomenon. When the charge sharing phenomenon occurs, the sensitivity of an output image is reduced and an image error can be generated.

Also, because a photo charge is not able to readily move between the photodiode and the readout circuitry, a dark current is generated and/or saturation and sensitivity is reduced.

### BRIEF SUMMARY

Embodiments of the present invention provide an image sensor where a readout circuitry and an image sensing device can be connected to each other through capacitance, and a method for manufacturing the same.

Embodiments also provide an image sensor where a charge sharing phenomenon can be inhibited while also increasing a fill factor, and a method for manufacturing the same.

Embodiments also provide an image sensor that can minimize a dark current source and inhibit saturation reduction and sensitivity degradation by forming a smooth transfer path of a photo charge between a photodiode and a readout circuitry, and a method for manufacturing the same.

In one embodiment, an image sensor can comprise: a readout circuitry at a first substrate; a metal line on the first substrate, the metal line being electrically connected to the readout circuitry; an insulation layer on the metal line; an electrode on the insulation layer; an image sensing device on the electrode; and a pixel separation region in the image sensing device.

In another embodiment, a method for manufacturing an image sensor can comprise: forming a readout circuitry on a first substrate; forming a metal line on the first substrate, the metal line being electrically connected to the readout circuitry; forming an image sensing device on a second substrate; forming an electrode on the image sensing device; forming an insulation layer on the electrode; bonding the first substrate and the second substrate such that the insulation layer of the second substrate contacts the first substrate; and forming a pixel separation region in the image sensing device.

In yet another embodiment, a method for manufacturing an image sensor can comprise: forming a readout circuitry on a first substrate; forming a metal line on the first substrate, the metal line being electrically connected to the readout circuitry; forming an electrode on the metal line; forming an insulation layer on the electrode; forming an image sensing device on a second substrate; bonding the first substrate and the second substrate such that the electrode contacts the image sensing device; and forming a pixel separation region in the image sensing device.

The details of one or more embodiments are set forth in the accompanying drawings and the detailed description below. Other features will be apparent to one skilled in the art from the detailed description, the drawings, and the appended eclaims.

### BRIEF DESCRIPTION OF THE DRAWINGS

FIG. 1 is a cross-sectional view showing an image sensor according to an embodiment of the present invention.

FIGS. 2 to 8 are cross-sectional views showing a method for manufacturing an image sensor according to an embodiment of the present invention.

FIG. 9 is a cross-sectional view showing an image sensor according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

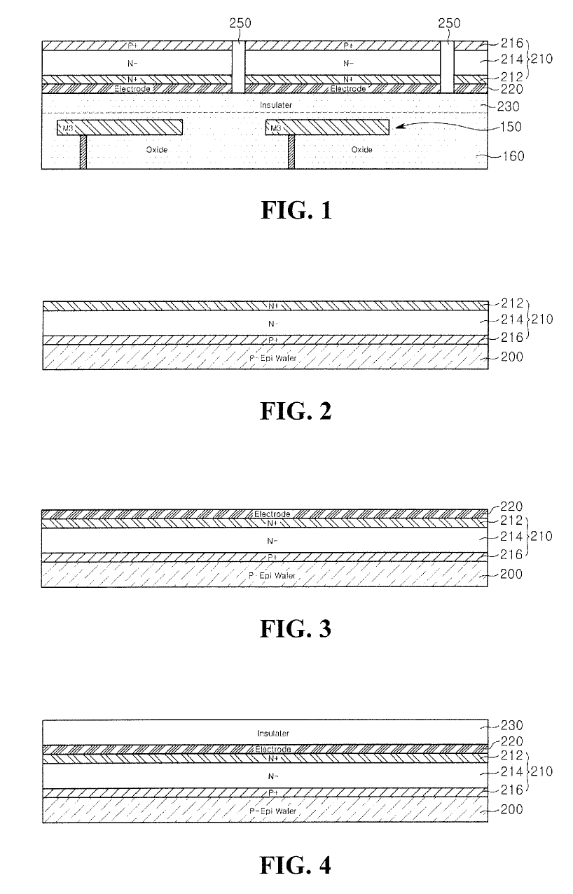

FIG. 1 is a cross-sectional view showing an image sensor according to an embodiment of the present invention.

Referring to FIG. 1, in an embodiment, an image sensor can include: a readout circuitry 120 disposed at a first substrate 100 (as shown in FIG. 5B); a metal line 150 disposed on the first substrate 100 and electrically connected to the readout circuitry 120; an insulation layer 230 disposed on the metal line 150; an electrode 220 disposed on the insulation layer 230; an image sensing device 210 disposed on the electrode 220; and a pixel separation region 250 disposed in the image sensing device 210.

The image sensing device 210 can be a photodiode, though embodiments of the subject invention are not limited thereto. For example, the image sensing device 210 can be a photogate, or a combination of a photodiode and a photogate. In one embodiment, the image sensing device 210 can be a photodiode formed in a crystalline semiconductor layer. In another embodiment, the image sensing device 210 can be a photodiode formed in an amorphous semiconductor layer.

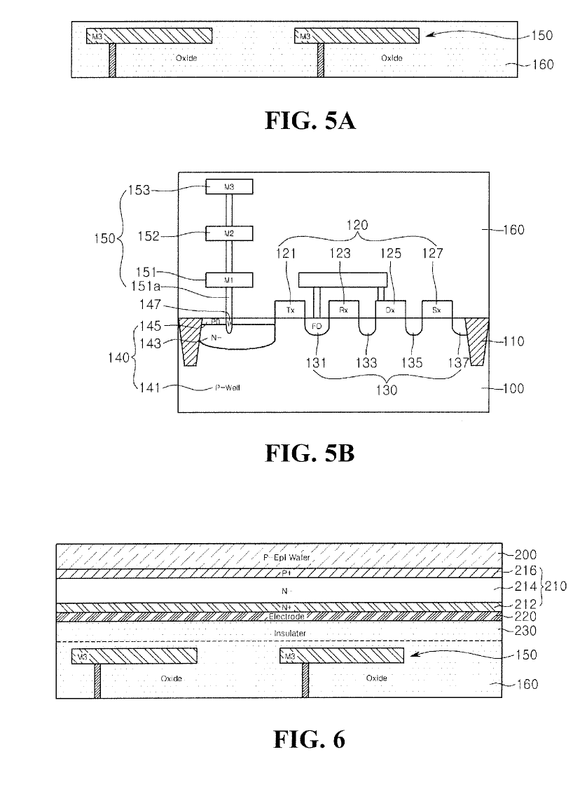

Hereinafter, a method for manufacturing an image sensor according to an embodiment will be described with reference to FIGS. 2 to 8.

Referring to FIG. 2, an image sensing device 210 can be formed on a second substrate 200. The image sensing device 210 can be, for example, a photodiode including a heavily-doped P-type conduction layer 216 and a lightly-doped N-type conductive layer 214 formed by implanting ions onto a crystalline semiconductor layer, though embodiments of the present invention are not limited thereto. In addition, a heavily-doped N-type (N+) conductive layer 212 can be formed on the lightly-doped N-type conductive layer 214 for the purpose of ohmic contact.

Then, referring to FIG. 3, an electrode 220 can be formed on the image sensing device 210. For example, the electrode 220 can be formed on the N+ conductive layer 212 of the image sensing device 210. The electrode 220 can be formed of any suitable material known in the art; for example, metal (e.g., Ti, TiN, Al, Ti, and/or TiN), polysilicon, or silicide.

Referring to FIG. 4, an insulation layer 230 can be formed on the electrode 220. The insulation layer 230 can be formed of any suitable material known in the art; for example, oxide, nitride/oxide, or oxide/nitride/oxide.

Next, referring to FIG. 5A, a first substrate 100 where the metal line 150 and the readout circuitry 120 are formed can be prepared. FIG. 5B is a detailed view of the first substrate 100 where the metal line 150 and the readout circuitry 120 are formed, and will be descried in more detail below.

Referring to FIG. 5B, the first substrate 100, in which the metal line 150 and the readout circuitry 120 are formed, can be prepared. For example, an active region can be defined by forming a device isolation layer 110 in the first substrate 100 of a second conductive type, and the readout circuitry 120 including transistors can be formed in the active region. For example, the readout circuitry 120 can include a transfer transistor (Tx) 121, a reset transistor (Rx) 123, a drive transistor (Dx) 125, and a select transistor (Sx) 127. An ion implantation region 130, including a floating diffusion region (FD) 131 and source/drain regions 133, 135, and 137 for the transistors, can be formed. Also, in an embodiment, a noise removing circuit (not shown) can be added to improve sensitivity.

In an embodiment, a method for manufacturing an image sensor can include forming an electrical junction region 140 in the first substrate 100 and forming a first conductive type connection 147 connected to the metal line 150 at an upper part of the electrical junction region 140.

For example, the electrical junction region 140 can be a P−N junction 140, though embodiments of the subject invention are not limited thereto. In an embodiment, the electrical junction region 140 can include a first conductive type ion implantation layer 143 formed on a second conductive type well 141 or a second conductive type epitaxial layer, and a second conductive type ion implantation layer 145 formed on the first conductive type ion implantation layer 143. For example, the electrical junction region 140 can be a P0 (145)/N− (143)/P− (141) junction, though embodiments of the subject invention are not limited thereto. The first substrate 100 can be a second conductive type substrate, though embodiments of the present invention are not limited thereto.

In an embodiment, the device can be designed to provide a potential difference between the source and drain of the transfer transistor (Tx), thereby enabling the full dumping of a photo charge. Accordingly, a photo charge generated in the photodiode can be dumped to the floating diffusion region, thereby increasing the output image sensitivity.

Specifically, electrons generated in the photodiode 210 can be transferred to the electrical junction region 140, and they can be transferred to the floating diffusion (FD) 131 node to be converted into a voltage when the transfer transistor (Tx) 121 is turned on.

The maximum voltage of the electrical junction region 140 (e.g., a P0/N−/P− junction can become a pinning voltage, and the maximum voltage of the FD 131 node can become Vdd minus the threshold voltage (Vth) of the reset transistor (Rx), i.e., Vdd−Rx Vth. Therefore, due to a potential difference between the source and drain of the transfer transistor (Tx) 131, without charge sharing, electrons generated in the photodiode 210 on the chip can be completely dumped to the FD 131 node.

Thus, unlike a related art device where a photodiode is simply connected to an N+ junction, an embodiment of the present invention makes it possible to inhibit saturation reduction and sensitivity degradation.

The first conductive type connection 147 is formed between the photodiode and the readout circuitry to create a smooth transfer path of a photo charge, thereby making it possible to minimize a dark current source and inhibit saturation reduction and sensitivity degradation.

To this end, in an embodiment, an N+ doping region can be formed as the first conductive type connection 147 for an ohmic contact on the surface of the electrical junction region 140 (e.g., a P0/N−/P− junction). The N+ region (147) can be formed such that it penetrates the P0 region (145) to contact the N− region (143).

In an embodiment, the width of the first conductive type connection 147 can be minimized to inhibit the first conductive type connection 147 from being a leakage source. To this end, a plug implant can be performed after etching a contact hole for a first metal contact 151a, though embodiments of the present invention are not limited thereto. For example, an ion implantation pattern (not shown) can be formed, and the ion implantation pattern can be used as an ion implantation mask when forming the first conductive type connection 147.

Next, an interlayer dielectric 160 can be formed on the first substrate 100, and the metal line 150 can be formed. The metal line 150 can include, for example the first metal contact 151a, a first metal 151, a second metal 152, and a third metal 153, though embodiments of the subject invention are not limited thereto.

In an embodiment, the top metal, e.g., the third metal 153 can be broadly formed and can have a smaller width than the electrode 220, thus making it possible to increase the capacitance of a capacitor and also to increase the light-receiving capability of the image sensing device due to the reflection of light.

Next, referring to FIG. 6, the first and second substrates 100 and 200 can be bonded to each other such that the insulation layer 230 contacts the first substrate 100. For example, the bonding of the first and second substrates 100 and 200 can be performed by interposing the insulation layer 230 so that the metal line 150 does not contact the image sensing device 210.

Referring to FIG. 7, the second substrate 200 can be removed (while the image sensing device 210 is not removed). For example, the second substrate 200 on the bonded chip can be cut on such that the heavily-doped P-type (P+) conductive layer 216 is exposed.

Referring to FIG. 8, a pixel separation region 250 can be formed in the image sensing device 210 over the chip to realize pixel-to-pixel isolation. The pixel separation region 250 can be formed through shallow trench isolation (STI) technique filling an insulation layer after etching a boundary between pixels. Alternatively, the pixel separation region 250 can be formed by implanting ions of a second conductive type, (e.g., p-type) in the boundary between the pixels.

Then, the P+ conductive layer 216 disposed over the chip can be connected to a ground line through a subsequent process.

During circuit operation according to an embodiment, a voltage of the photodiode decreases when photoelectrons are generated during light integration. The photoelectrons can be transferred to the readout circuitry 120 of the silicon substrate through capacitance formed between a metal (e.g., a third metal 153—M3) and the electrode 220 over the chip. Accordingly, a voltage variation according to the number of electrons generated by light can be sensed, thereby realizing an image signal.

In an embodiment, a height of the transistor in the readout circuitry 120 of the first substrate 100 can be from about 5 to about 15 times larger than the distance between the metal line 150 and the electrode 220 after bonding. Consequently, the voltage variation according to electrons generated by light can be effectively transferred to the readout circuitry 120.

In an image sensor and method for manufacturing the same according to an embodiment of the present invention, the image sensing device over the chip and the readout circuitry of the silicon substrate can be connected to each other using capacitance. Therefore, it is not necessary to perform a process of forming a contact between the image sensing deice and the metal line. Accordingly, a manufacturing process of a 3-D image sensor can be facilitated, and it is also possible to inhibit a dark current caused by the contact formation.

In a particular embodiment of the subject invention, the insulation layer 230 and the electrode 220 can be sequentially formed on the metal line 150.

Then, the image sensing device 210 can be formed on the second substrate 200, and the first and second substrates 100 and 200 can be bonded, thus bringing the electrode 220 into contact with the image sensing device 210.

=According to this embodiment, the image sensing device over the chip and the readout circuitry of the silicon substrate can be connected to each other using capacitance. Therefore, it is not necessary to perform a process of forming a contact between the image sensing deice and the metal line. Accordingly, a manufacturing process of a 3-D image sensor can be facilitated, and it is also possible to inhibit a dark current caused by the contact formation.

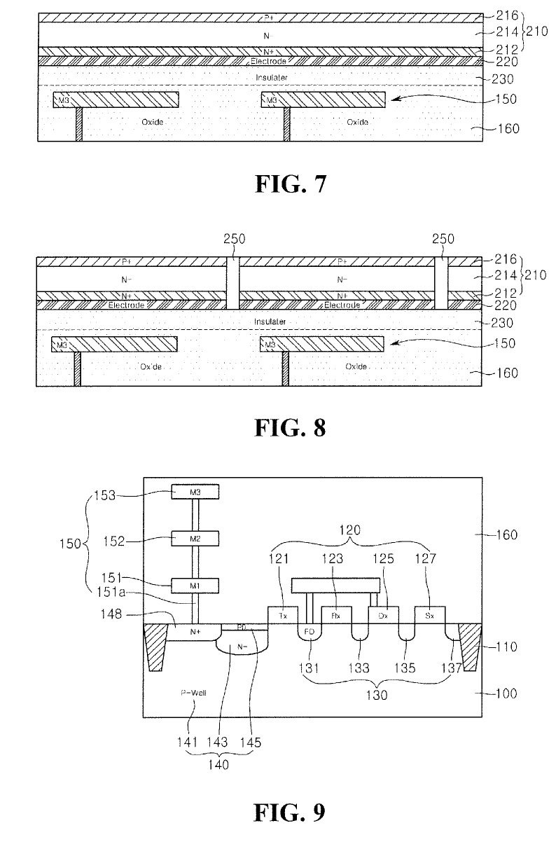

FIG. 9 is a cross-sectional view showing an image sensor according to an embodiment of the subject invention. FIG. 9 particularly shows a detailed view of the first substrate with the metal line 150.

Referring to FIG. 9, a first conductive type connection 148 can be disposed at a side of (and electrically connected to) the electrical junction region 140.

The first conductive type connection 148, which can be for example an N+ connection region, can be formed at a side of the electrical junction 140 (e.g., a P0/N−/P− junction) for an ohmic contact. In this case, a leakage source can sometimes be generated during the formation process of the N+ connection region 148 and the first metal contact 151a. Also, when the N+ connection region 148 is formed over the surface of the PNP (P0/N−/P−) junction 140, an electric field can also be generated due to the N+/P0 junction 148/145. This electric field can also become a leakage source.

Accordingly, in an embodiment of the present invention, a layout is provided in which the first contact plug 151a can be formed in an active region not doped with a P0 layer, but rather includes an N+ connection region 148 that is electrically connected to the N− layer 143.

According to this embodiment, the electric field may not be generated on and/or over an Si surface, and this embodiment can contribute to reduction in a dark current of a 3D integrated CIS.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry at a first substrate;
a metal line on the first substrate, the metal line being electrically connected to the readout circuitry;
an insulation layer on the metal line;
an electrode on the insulation layer;
an image sensing device on the electrode; and
a pixel separation region in the image sensing device.

2. The image sensor according to claim 1, wherein a height of a transistor in the readout circuitry is about 5 times to about 15 times larger than a distance between the electrode and the metal line.

3. The image sensor according to claim 1, further comprising an electrical junction region in the first substrate, the electrical junction region being electrically connected to the readout circuitry.

4. The image sensor according to claim 3, wherein the electrical junction region comprises:
a first conductive type ion implantation region in the first substrate; and
a second conductive type ion implantation region on the first conductive type ion implantation region.

5. The image sensor according to claim 3, further comprising a first conductive type connection between the electrical junction region and the metal line.

6. The image sensor according to claim 5, wherein the first conductive type connection is disposed on the electrical junction region and is electrically connected to the metal line.

7. The image sensor according to claim 5, wherein the first conductive type connection is disposed at a side of the electrical junction region and is electrically connected to the metal line.

8. The image sensor according to claim 3, wherein the readout circuitry comprises at least one transistor having a source and a drain, and wherein the readout circuitry has a potential difference between the source and the drain of the at least one transistor.

9. The image sensor according to claim 8, wherein the transistor is a transfer transistor, and
wherein the source of the transistor has a lower ion implantation concentration than that of a floating diffusion region of the readout circuitry.

10. The image sensor according to claim 3, wherein the electrical junction region comprises a PN junction.

11. A method for manufacturing an image sensor, the method comprising:
forming a readout circuitry on a first substrate;
forming a metal line on the first substrate, the metal line being electrically connected to the readout circuitry;
forming an image sensing device on a second substrate;
forming an electrode on the image sensing device;
forming an insulation layer on the electrode;
bonding the first substrate and the second substrate such that the insulation layer of the second substrate contacts the first substrate; and
forming a pixel separation region in the image sensing device.

12. The method according to claim 11, wherein the bonding of the first substrate and the second substrate comprises interposing the insulation layer and the electrode such that the metal line does not contact the image sensing device.

13. The method according to claim 11, further comprising forming an electrical junction region in the first substrate, the electrical junction region being electrically connected to the readout circuitry.

14. The method according to claim 13, further comprising forming a first conductive type connection between the electrical junction region and the metal line.

15. The method according to claim 14, wherein the first conductive type connection is on the electrical junction region and electrically connected to the metal line.

16. The method according to claim 13, wherein forming the electrical junction region comprises:
forming a first conductive type ion implantation region on the first substrate; and
forming a second conductive type ion implantation region on the first conductive type ion implantation region.

17. A method for manufacturing an image sensor, the method comprising:
forming a readout circuitry on a first substrate;
forming a metal line on the first substrate, the metal line being electrically connected to the readout circuitry;
forming an electrode on the metal line;
forming an insulation layer on the electrode
forming an image sensing device on a second substrate;
bonding the first substrate and the second substrate such that the electrode contacts the image sensing device; and
forming a pixel separation region in the image sensing device.

18. The method according to claim 17, further comprising forming an electrical junction region in the first substrate, the electrical junction region being electrically connected to the readout circuitry.

19. The method according to claim 18, further comprising forming a first conductive type connection between the electrical junction region and the metal line.

20. The method according to claim 19, wherein the first conductive type connection is disposed at a side of the electrical junction region and electrically connected to the metal line.
